(19) United States
(12) Patent Application Publication
(10) Pub. No.: US 2009/0309189 A1
(43) Pub. Date: Dec. 17, 2009

(54) METHOD FOR THE GROWTH OF INDIUM NITRIDE

(75) Inventors: Sandra Clur Ruffenach, Montarnaud (FR); Olivier Briot, Jacou (FR); Bernard Gil, Montpellier (FR)

Correspondence Address: YOUNG & THOMPSON, 209 Madison Street, Suite 500, Alexandria, VA, 22314, US

(73) Assignees: CENTRE NATIONAL DE LA RECHERCHE SCIENTIFIQUE (C.N., Paris (FR); UNIVERSITE DE MONTPELLIER II, Montpellier Cedex 05 (FR)

(21) Appl. No.: 12/374,026

(22) PCT Filed: Jul. 16, 2007
(86) PCT No.: PCT/FR2007/001216

§ 371 Date: Jul. 14, 2009

(30) Foreign Application Priority Data
Jul. 18, 2006 (FR) 06 06522

(51) Int. Cl. H01L 29/20; C30B 25/00

(52) U.S. Cl. 257/615; 117/104; 257/E29.089

(57) ABSTRACT

The present application relates to a method for the growth of indium nitride on a substrate by means of MOVPE in the presence of a noble gas as growth vector.

The present invention relates to the field of nanotechnology employed in the manufacture of electronic devices and, more precisely, to a novel method for the growth of nitrides of group IIIb elements.

Some group IIIb metal nitrides, in particular indium and gallium nitrides, have electronic properties which are very beneficial for electronic and optoelectronic applications. As these materials have exceptional saturation rates, they can be considered for the production of transistors operating at very high frequencies. In addition, terahertz radiation can be emitted from these materials.

There has been a growing interest in indium nitride since it was discovered that its forbidden band could be close to 0.7-0.75 eV which is the window used for infrared communications. Combined with gallium nitride, therefore, indium nitride covers the infrared range with emissions, in particular, at 1.3 μm and 1.55 μm for telecommunications applications, but also for the visible range with emission in the red.

It has also been demonstrated that single photon emitters can be produced from nanometric semiconductor devices known as quantum dots.

Up until now, however, the development of InN-based technologies has been limited by the difficulties associated with the growth of this material.

In fact, there are no substrates available with suitable lattice parameters, so it is necessary to use alternative double step methods of growth. This method, which was developed for MBE by S. Yoshida (S. Yoshida et al. J. Appl. Phys. 53(10), (1982) 6844) and taken up again for MOCVD by Amano and Akasaki (H. Amano et al., Appl. Phys. Lett. 48, (1986) 353), involves producing, between the substrate and the layer of desired material, an intermediate layer of this same material or of a material having a compatible lattice parameter and structure deposited at a lower temperature than the crystalline material. This intermediate layer, which is commonly known as a buffer in particular enables the effects associated with differences between lattice parameter and coefficient of thermal expansion to be absorbed and therefore enables the crystalline quality of the final layer to be improved.

In addition, low dissociation temperature of indium nitride, which is less than 750°, preferably less than 700° C., lead to very low growth rates owing to the slow decomposition of ammonia which is the usual precursor of nitrogen for MOCVD growth.

The production of an InN film of sufficiently high quality, in particular in terms of crystallinity, for the preparation of a component necessarily involves the optimisation of the initial wetting of the substrate. This is an essential parameter which involves a high InN nucleation density on the surface. This is currently the limiting factor in conventional conditions of growth.

For the growth of indium nitride nano-objects such as quantum dots, it is also beneficial to control the nucleation density, i.e. the density of nano-objects both towards high densities for the production of standard devices such as light-emitting diodes, for example, and towards low densities for isolating a single nano-object.

Various methods for the growth of indium nitride on a substrate are known.

The application WO 2005/014897 describes a method for manufacturing indium nitride quantum dots comprising the growth of indium nitride on a layer having a similar lattice structure such as gallium nitride or aluminium nitride, by MOVPE (metal-organic vapour phase epitaxy) with trimethyl indium (TMIn) and ammonia as precursors.

With this method, the size of the dots obtained depends on the growth temperature, the molar ratio of the precursors and the deposition time. The described method enables an indium nitride quantum dot density of less than 10⁸ cm⁻², and generally of about 10⁷ cm⁻² to be obtained by modifying the parameters. In practice, however, adjustment of these parameters may be time-consuming and difficult owing to their complex interactions.

The application FR 2 875 333 describes the production of a layer of indium nitride on a layer of alloy of at least one atomic element from column II of the periodic table and/or at least one atomic element from column IV of the periodic table and N₂ (II-IV-N₂) by MOVPE. This method does not teach modulation of the nucleation density of the material.

It is the object of the present invention to propose a method for the growth of InN which overcomes the drawbacks of the prior art and, in particular, enables a control of the nucleation density of the material.

The proposed method of growth by MOVPE is based on the use of noble gases as carrier gases. It enables the control of the nucleation density of the indium nitride on a material. It applies equally to the growth of films, of heterostructures and of nanostructures.

The inventors have surprisingly found that the use of a noble gas during growth enables the nucleation density of the material to be modified. It is found that the presence of the noble gas affects the nucleation density of the material.

The nucleation density may be increased or reduced by the presence of the noble gas, depending on the choice of noble gas, all other parameters of the method remaining constant. Therefore, the nucleation density can also be varied easily toward higher and lower densities, without changing the parameters of the method.

This method is also advantageous in that it does not require a modification of the apparatus and may be carried out on conventional equipment.

According to a first feature, the present invention relates to a method for the growth of InN on a substrate, wherein said step of growth is produced by MOVPE in the presence of a noble gas.

Said noble gas may be selected from helium, neon, argon, krypton, xenon and radon or a mixture thereof. Helium and argon are preferred on account of their availability.

The term MOVPE (metal organic vapour phase epitaxy) or MOCVD (metal organic chemical vapour deposition) refers to organometallic vapour phase epitaxy.

MOVPE involves forming layered structures by atom deposition on a substrate. It is generally carried out in the gaseous phase under moderate pressure (typically from a few millibars to atmospheric pressure) using gaseous organometallic precursors, contrary to molecular beam epitaxy (MBE) which is carried out in ultra-high vacuum generally, starting from solid sources.

Growth by MOVPE is known as such and may be carried out by the person skilled in the relevant art. A method of growth by MOVPE of this type is described, for example, in the application WO 2005/014897 and in the work by G. B. Stringfellow, “Organometallic vapor-phase epitaxy: Theory and Practice”, Academic Pres, San Diego Calif. (1989).

According to the invention, the term “film” denotes a continuous layer, preferably a thin layer, generally having a thickness of between a single atom monolayer and 10 microns.

According to the invention, the term “nano-object” denotes an individual structure, at least one dimension of which has a nanometric size of between 1 and 50 nm.

The method is quick and easy to carry out. Although the addition of a specific incoming line for the noble gas may be considered in certain cases, this is not necessary and standard MOCVD growth equipment may be used.

Preferably, the starting materials and the normal deposition conditions are not changed. The method is particularly advantageous in that it enables the nucleation density to be changed without having to adjust the highly interdependent method parameters.

The choice of the substrate is not particularly limited. It is selected from conventionally used substrates as a function of the material to be deposited and its structure. It may be, in particular, sapphire, SiC, Si or GaN. It generally has a thickness of several hundreds of microns.

The substrate may be coated with a layer of material selected from AIN, GaN, SiC, Si, InGaN and AlInGaN. GaN will preferably be selected.

The epitaxy surface of the substrate may be worked to improve its physical properties for growth. One or more of the following techniques may be employed: polishing, chemical etching or other techniques known to the person skilled in the art.

The material is formed by thermal decomposition of the precursors and reaction between the decomposition products.

Appropriate precursors are selected from derivatives having limited thermal stability.

Nitrogen may easily be contributed, for example, by ammonia of dimethylhydrazine.

Indium precursors may be selected from organometallic compounds. More particularly, alkyl derivatives, for example methyl and ethyl derivatives such as trimethyl indium and triethyl indium may be used.

The precursors are generally in a gaseous, liquid or solid form. A carrier gas is therefore used to entrain the precursors and produce a laminar gas flow in the reactor.

According to the invention, the carrier gas consists totally or partially of a noble gas. It is thus possible to use a carrier gas comprising a noble gas and a conventional carrier gas such as nitrogen or hydrogen.

The molar ratio of the gaseous phase precursors is adjusted so as to obtain that of the desired solid phase material. The amount of carrier gas will basically depend on the growth equipment used.

The total pressure is generally between about 20 millibars and atmospheric pressure.

The growth temperature depends, in particular, on the constitution of the layer to be deposited and the selected precursor. For example, it is generally 750° C. or less, in particular between 250° C. and 650° C. in the case of InN.

Growth by MOVPE in the presence of a noble gas enables the nucleation density of the material to be changed. The direction of control of nucleation density (increase or decrease) depends on the nature of the selected noble gas.

A simple tool is thus available for controlling the nucleation density of InN deposited on a substrate, without changing the other parameters of the method.

The InN elements may be, in particular, films or nano-objects such as quantum dots.

Advantageously, the height of the nano-objects is not affected by the presence of the noble gas, so control of the emission characteristics (wavelength, efficiency, etc) associated with confinement in the dots is maintained.

With identical deposition parameters, therefore, the described method allows films and nano-objects of the materials in question having a higher or lower nucleation density to be obtained.

According to another feature, the present invention accordingly relates to a substrate carrying a film or one or more nano-objects made of the material which are obtainable by this method.

In particular, the present invention covers indium nitride films and nano-objects having a nucleation density of 10⁹ cm ⁻², preferably 10¹⁰ cm⁻² or more.

Similarly, the present invention also covers indium nitride films or nano-objects having a nucleation density of less than 10⁷ cm⁻², preferably 10⁶ cm⁻².

Depending on the noble gas used, a field of application of a method of growth characterised by a given set of deposition parameters may thus be extended.

According to yet another feature, the invention relates to the use of a noble gas as a carrier gas in the growth of indium nitride by MOVPE for modifying the nucleation density.

The method of growth thus allows access to the single nano-object but also to a high nano-object density or a film having a high nucleation density, which can be used for standard optoelectronic components.

According to a last feature, therefore, the present invention also relates to components comprising a film or nano-object as described hereinbefore.

Said components are useful, in particular, in the field of optoelectronics. They may be, for example, light-emitting diodes, laser diodes or transistors.

### FIGURES

FIG. 1 shows microscopic images on an atomic scale of indium nitride nano-objects on a GaN substrate (2 μm×2 μm).

FIG. 1A shows InN nano-objects obtained using nitrogen as the carrier gas as in Example 1;

FIG. 1B shows InN nano-objects obtained using argon as the carrier gas as in Example 2; and

FIG. 1C shows InN nano-objects obtained using helium as the carrier gas as in Example 3.

The following are non-limiting examples of the present invention.

### EXAMPLE

### Example 1

### Deposition of Quantum Dots of InN with Nitrogen as the Carrier Gas

In a device for growth by MOVPE (Aixtron: AIX200/4RF-S), InN quantum dots are grown on an “epi-ready” sapphire substrate (0001), polished on one face.

The following precursors are used: trimethyl indium (TMI), trimethyl gallium (TMGa) and NH₃. Hydrogen is used as the carrier gas except in step 5, where nitrogen is used.

More specifically, the steps of the method of growth employed are as follows:
1. Desorption of the substrate: 10 minutes at 1200° C. at 100 mBar;
2. Deposition of a buffer layer of GaN having a thickness of 25 nm at 540° C., 200 mBar with 3000 sccm (sccm=standard cm³/minute) of NH₃ and 10 sccm of TMGa cooled to 0° C.;
3. Recrystallisation of the buffer layer of GaN for 1 minute at 1050° C., 200 mBar, with 2000 sccm of NH₃;
4. Growth of the GaN layer having a thickness of 1 μm at 1090° C., 200 mBar with 2000 sccm of NH₃ and 15 sccm of TMGa cooled to 0° C.;
5. Growth of InN dots having an average height of 22 nm: 45 s of growth at 550° C., 200 mBar with 7000 sccm of NH₃ and 643 sccm of TMI (20° C.);

The fluxes entering the reactor are strictly or as closely as possible in a ratio by volume of NH₃ on one hand to TMI and TMGa on the other hand of 7:1, the NH₃ and organometallic precursors being injected separately.

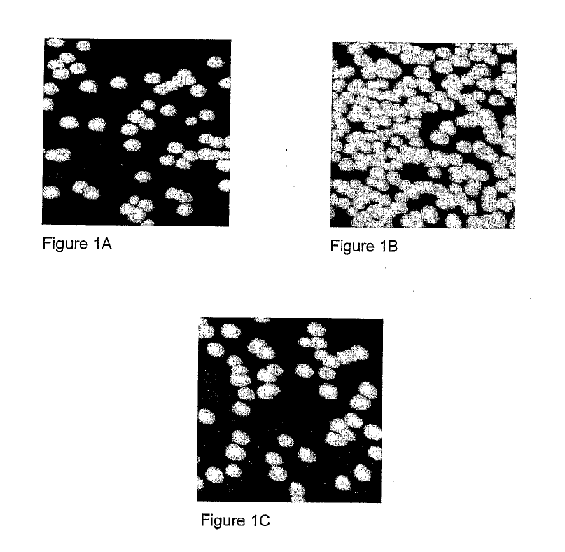

FIG. 1A is a microscopic image on an atomic scale of the sample obtained. A density of indium nitride nano-objects having a density of approximately 1.6×10⁹ cm⁻² is determined by counting.

### Example 2

### Deposition of Quantum Dots of InN with Argon as the Carrier Gas

The method adopted in Example 1 was followed, except that the nitrogen used as the carrier gas in step 5 was replaced by argon.

FIG. 1B is a microscopic image on an atomic scale of the sample obtained. A density of indium nitride nano-objects having a density of approximately 7×10⁹ cm⁻² is determined by counting. This corresponds to an increase of approximately 340% over Example 1, where nitrogen was used as the carrier gas.

### Example 3

### Deposition of Quantum Dots of InN with Helium as the Carrier Gas

The method adopted in Example 1 was followed, except that the nitrogen used as the carrier gas in step 5 was replaced by helium.

FIG. 1C is a microscopic image on an atomic scale of the sample obtained. A density of indium nitride nano-objects having a lower density of 10⁹ cm⁻² is determined by counting. This corresponds to a decrease of approximately 38% over Example 1, where nitrogen was used as the carrier gas.

In Examples 2 and 3, the heights of the nano-objects obtained are almost identical to the heights obtained using nitrogen. Only the shape has changed slightly.

In the investigated system, therefore, a change of carrier gas alters the density, slightly alters the diameter, but does not alter the height of the nano-objects. This feature is important in so far as the confinement in the dots and therefore the efficiency of emission depend on the dimensions of the dot and therefore its height.

1-12. (canceled)

13. Method for the growth of InN on a substrate, wherein the step of growth is carried out by MOVPE in the presence of a noble gas.

14. Method according to claim 13, wherein said noble gas is selected from helium or argon.

15. Method according to claim 13, wherein the step of growth is carried out by MOVPE at a temperature of between 250° C. and 750° C.

16. Method according to claim 13, wherein the substrate is selected from sapphire, AIN, GaN, SiC or Si.

17. Method according to claim 13, wherein said substrate is coated beforehand with a layer of GaN.

18. Method for modifying the nucleation density in the growth of indium nitride on a substrate by MOVPE comprising the use of a noble gas as the carrier gas.

19. Structure of indium nitride disposed on a substrate which is obtainable by the method according to claim 13.

20. Structure of indium nitride disposed on a substrate which is obtainable by the method according to claim 14.

21. Structure of indium nitride disposed on a substrate which is obtainable by the method according to claim 15.

22. Structure of indium nitride disposed on a substrate which is obtainable by the method according to claim 16.

23. Structure of indium nitride disposed on a substrate which is obtainable by the method according to claim 17.

24. Structure of indium nitride disposed on a substrate which is obtainable by the method according to claim 18.

25. Structure according to claim 19 in the form of a film or nano-objects disposed on the substrate.

26. Structure according to claim 19, having a nucleation density of 10¹⁰ cm⁻² or more.

27. Structure according to claim 19, having a nucleation density of less than 10⁸ cm⁻².

28. Component comprising a structure according to claim 19.

29. Component according to claim 28, selected from light-emitting diodes, laser diodes and transistors.
